(19) United States
(12) Patent Application Publication
(10) Pub. No.: US 2025/0081736 A1
(43) Pub. Date: Mar. 6, 2025

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Hongting Lu, Beijing (CN); Changchang Liu, Beijing (CN); Fei Fang, Beijing (CN); Ling Shi, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/288,919

(22) PCT Filed: Jan. 18, 2023
(86) PCT No.: PCT/CN2023/072832

§ 371 Date: Oct. 30, 2023

(30) Foreign Application Priority Data
Nov. 30, 2022 (CN) 202211534232.6

(51) Int. Cl. H10K 59/122; H10K 59/131; H10K 59/80

(52) U.S. Cl. CPC H10K 59/122; H10K 59/131; H10K 59/80515; H10K 59/8792

(57) ABSTRACT

The present disclosure provides a display substrate and a display device. The display substrate includes a base substrate and a plurality of sub-pixels arranged on the base substrate, at least one sub-pixel includes a sub-pixel driving circuit and a light-emitting element, the light-emitting element includes an anode pattern, and the anode pattern is coupled to the sub-pixel driving circuit. The display substrate further includes a plurality of pixel definition patterns, and an orthographic projection of at least one pixel definition pattern onto the base substrate at least partially overlaps with an orthographic projection of a boundary of a corresponding anode pattern onto the base substrate.

### CROSS-REFERENCE TO RELATED APPLICATIONS

This application claims priority to Chinese Patent Application No. 202211534232.6 filed in China on Nov. 30, 2022, which is incorporated by reference herein in its entirety.

### TECHNICAL FIELD

The present disclosure relates to the field of display technologies, in particular to a display substrate and a display device.

### BACKGROUND

The Full Display With Camera (FDC) technology is to hide a front-facing camera under a display screen, and a region where the camera is located can display an image normally, thereby to completely remove a bang and a frame of the display product, and realize a full-screen display in a real sense.

### SUMMARY

The present disclosure is to provide a display substrate and a display device.

In order to achieve the above object, the present disclosure provides the following technical solutions:

In a first aspect, the present disclosure provides a display substrate, including: a base substrate and a plurality of sub-pixels arranged on the base substrate, where at least one sub-pixel includes a sub-pixel driving circuit and a light-emitting element, the light-emitting element includes an anode pattern, and the anode pattern is coupled to the sub-pixel driving circuit. The display substrate further includes a plurality of pixel definition patterns, an orthographic projection of at least one pixel definition pattern onto the base substrate at least partially overlapping with an orthographic projection of a boundary of a corresponding anode pattern onto the base substrate.

In some embodiments of the present disclosure, the orthographic projection of the pixel definition pattern onto the base substrate fully covers the orthographic projection of the boundary of the corresponding anode pattern onto the base substrate.

In some embodiments of the present disclosure, at least a portion of the orthographic projection of the pixel definition pattern onto the base substrate has an annular structure, and the annular structure is configured to define an opening region of a corresponding sub-pixel.

In some embodiments of the present disclosure, at least a portion of the orthographic projection of the pixel definition pattern onto the base substrate has a circular-annular structure.

In some embodiments of the present disclosure, the anode pattern includes an anode main body and an anode connection member coupled to each other, and the anode connection member is coupled to a corresponding sub-pixel driving circuit. The pixel definition pattern includes a first sub-pattern and a second sub-pattern coupled to each other, an orthographic projection of the first sub-pattern onto the base substrate has an anular structure, the orthographic projection of the first sub-pattern onto the base substrate covers an orthographic projection of a boundary of a corresponding anode main body onto the base substrate, and an orthographic projection of the second sub-pattern onto the base substrate covers an orthographic projection of a corresponding anode connection member onto the base substrate.

In some embodiments of the present disclosure, the pixel definition pattern includes a black pixel definition pattern; an orthographic projection of the pixel definition pattern onto the base substrate at least partially overlaps with an orthographic projection of a corresponding sub-pixel driving circuit onto the base substrate.

In some embodiments of the present disclosure, the display substrate further includes a transparent data line, and at least a portion of an orthographic projection of the transparent data line onto the base substrate is located between orthographic projections of adjacent pixel definition patterns onto the base substrate.

In some embodiments of the present disclosure, the display substrate further includes a transparent reset signal line, and at least a portion of an orthographic projection of the transparent reset signal line onto the base substrate is located between orthographic projections of adjacent pixel definition patterns onto the base substrate.

In some embodiments of the present disclosure, the display substrate includes an initialization signal line, the initialization signal line includes a transparent initialization portion, and at least a portion of an orthographic projection of the transparent initialization portion onto the base substrate is located between orthographic projections of adjacent pixel definition patterns onto the base substrate.

In some embodiments of the present disclosure, the sub-pixel driving circuit includes a data written-in transistor, the display substrate includes a first scanning line, a gate electrode of the data written-in transistor is coupled to a corresponding first scanning line, the first scanning line includes a first transparent scanning portion, an orthographic projection of the first transparent scanning portion onto the base substrate is located between orthographic projections of adjacent pixel definition patterns onto the base substrate.

In some embodiments of the present disclosure, the sub-pixel driving circuit includes a compensation transistor, the display substrate includes a second scanning line, a gate electrode of the compensation transistor is coupled to a corresponding second scanning line, the second scanning line includes a second transparent scanning portion, an orthographic projection of the second transparent scanning portion onto the base substrate is located between orthographic projections of adjacent pixel definition patterns onto the base substrate.

In some embodiments of the present disclosure, the display substrate includes a light-emission control signal line, the light-emission control signal line includes a transparent light-emission control portion, at least a portion of an orthographic projection of the transparent light-emission control portion onto the base substrate is located between orthographic projections of adjacent pixel definition patterns onto the base substrate.

In some embodiments of the present disclosure, the display substrate further includes a power source line, the power source line includes a transparent power source portion, and an orthographic projection of the transparent power source portion onto the base substrate is located between orthographic projections of adjacent pixel definition patterns onto the base substrate.

In some embodiments of the present disclosure, the display substrate further includes a cathode layer located on a side of the light-emitting element away from the base substrate, the cathode layer includes a plurality of cathode openings, and at least a portion of an orthographic projection of at least one cathode opening onto the base substrate is located between orthographic projections of adjacent pixel definition patterns onto the base substrate.

In some embodiments of the present disclosure, the orthographic projection of the cathode opening onto the base substrate is between the orthographic projections of the adjacent pixel definition patterns onto the base substrate.

In some embodiments of the present disclosure, the display substrate further includes an encapsulation layer and a plurality of black matrix patterns, the encapsulation layer is located between the plurality of black matrix patterns and the base substrate, an orthographic projection of at least one black matrix pattern onto the base substrate at least partially overlaps with an orthographic projection of a corresponding pixel definition pattern onto the base substrate.

In some embodiments of the present disclosure, the orthographic projection of the black matrix pattern onto the base substrate has an annular structure, and an orthographic projection of an inner boundary of the black matrix pattern onto the base substrate surrounds an orthographic projection of an inner boundary of the corresponding pixel definition pattern onto the base substrate.

In some embodiments of the present disclosure, an orthographic projection of an outer boundary of the pixel definition pattern onto the base substrate surrounds an orthographic projection of the corresponding black matrix pattern onto the base substrate.

In some embodiments of the present disclosure, the display substrate includes a first display region and a second display region, the second display region is located on at least one side of the first display region, and a light transmittance of the first display region is greater than a light transmittance of the second display region, and the plurality of pixel definition patterns is located in the first display region.

Based on the specific structure of the above-mentioned display substrate, in a second aspect, the present disclosure provides a display device, including the above-mentioned display substrate, and a sensor located on a non-display side of the display substrate, and an orthographic projection of the sensor onto the display substrate overlaps with the first display region of the display substrate.

### BRIEF DESCRIPTION OF THE DRAWINGS

The following drawings are provided to facilitate the understanding of the present disclosure, and constitute a portion of the present disclosure. These drawings and the following embodiments are for illustrative purposes only, but shall not be construed as limiting the present disclosure. In these drawings,

FIG. 1 is a schematic view showing the layout of a sub-pixel driving circuit and a pixel definition layer in a display substrate according to one embodiment of the present disclosure;

FIG. 2 is a schematic circuit diagram of the sub-pixel driving circuit according to one embodiment of the present disclosure:

FIG. 3 is a signal timing sequence diagram of the sub-pixel driving circuit in FIG. 2;

FIG. 4 is a circuit layout design of the sub-pixel driving circuit according to one embodiment of the present disclosure;

FIGS. 5 to 33 are schematic views showing respective film layers of the sub-pixel driving circuit in FIG. 4 and structures of partial film layers laminated one on another.

FIG. 34 is a schematic view showing the layout of a case where a black matrix pattern is added into a structure in FIG. 38;

FIG. 35 is a schematic view showing an anode pattern according to one embodiment of the present disclosure;

FIG. 36 is a schematic view showing a pixel definition pattern according to one embodiment of the present disclosure;

FIG. 37 is a schematic view showing the layout of the anode pattern and the pixel definition pattern according to one embodiment of the present disclosure:

FIG. 38 is a schematic view showing the layout of a case where a cathode layer is added on the basis of FIG. 37;

FIG. 39 is a schematic view showing a black matrix pattern according to one embodiment of the present disclosure:

FIG. 40 is a schematic view showing a display substrate according to one embodiment of the present disclosure;

FIG. 41 is a schematic view showing a display device according to one embodiment of the present disclosure.

### DETAILED DESCRIPTION

In order to further explain the display substrate and the display device in the embodiments of the present disclosure, a detailed description will be given below with reference to the accompanying drawings.

In the related art, in a display product using full display with camera (FDC) technology, a method of increasing transmittance includes: reducing the quantity of via-holes, compressing process limits and hiding all metal layers except an anode below the anode, etc. However, there is a great difficulty in the process in the above-mentioned method. Therefore, there is an urgent need for a new way to improve the transmittance of the display product using FDC technology.

With reference to FIGS. 35, 36 and 37, the present disclosure provides in some embodiments a display substrate including: a base substrate and a plurality of sub-pixels arranged on the base substrate, where at least one sub-pixel includes a sub-pixel driving circuit and a light-emitting element, the light-emitting element includes an anode pattern Ano, and the anode pattern Ano is coupled to the sub-pixel driving circuit. The display substrate further includes a plurality of pixel definition patterns BPDL, an orthographic projection of at least one pixel definition pattern BPDL onto the base substrate at least partially overlapping with an orthographic projection of a boundary of a corresponding anode pattern Ano onto the base substrate.

Illustratively, the display substrate includes the plurality of sub-pixels, and multiple sub-pixel driving circuits of the respective sub-pixels are arranged in an array form. The multiple sub-pixel driving circuits are divided into sub-pixel driving circuits in rows and sub-pixel driving circuits in columns. The sub-pixel driving circuits in rows are arranged in a second direction, and sub-pixel driving circuits in each row includes a plurality of sub-pixel driving circuits arranged in a first direction. The sub-pixel driving circuits in columns are arranged in the first direction, and sub-pixel driving circuits in each column includes a plurality of sub-pixel driving circuits arranged in the second direction. Illustratively, the first direction crosses the second direction. For example, the first direction includes a lateral direction and the second direction includes a longitudinal direction.

Illustratively, the sub-pixel includes the sub-pixel driving circuit and the light-emitting element. The sub-pixel driving circuit is coupled to the anode pattern Ano of the light-emitting element, and configured to apply a driving signal to the light-emitting element, so as to drive the light-emitting element to emit light.

Illustratively, the display substrate includes a first active layer, a first gate insulating layer, a first gate metal layer, a second gate insulating layer, a second gate metal layer, a third gate insulating layer, a second active layer, a third gate insulating layer, a third gate metal layer, an interlayer insulating layer, a first source/drain metal layer, a passivation layer, a first transparent metal layer, a first planarization layer, a second transparent metal layer, a second planarization layer, a second source/drain metal layer, a second planarization layer, an anode layer, a pixel definition layer, a light-emitting functional layer, a cathode layer and an encapsulation layer which are laminated one on another sequentially in a direction away from the base substrate.

Illustratively, the first active layer, the first gate insulating layer, the first gate metal layer, the second gate insulating layer, the second gate metal layer, the third gate insulating layer, the second active layer, the third gate insulating layer, the third gate metal layer, the interlayer insulating layer, the first source/drain metal layer, the passivation layer, the first transparent metal layer, the first planarization layer, the second transparent metal layer, the second planarization layer and the second source/drain metal layer are used for forming the sub-pixel driving circuit and some signal lines of the display substrate.

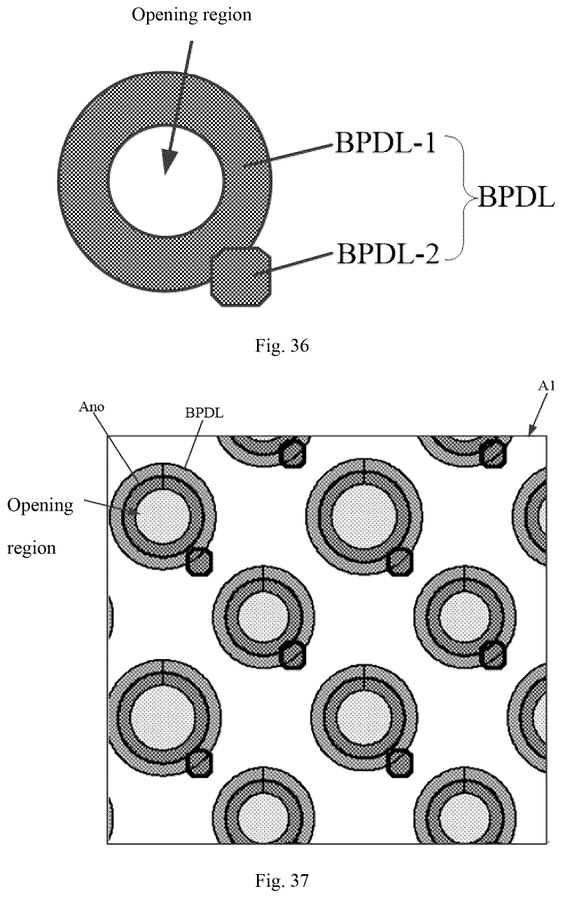

As shown in FIGS. 36 and 37, illustratively, the pixel definition layer includes the plurality of pixel definition patterns BPDL, and the pixel definition patterns BPDL are capable of defining opening regions of corresponding sub-pixels.

Illustratively, the plurality of pixel definition patterns BPDL are separate from each other, and arranged in an array form, and adjacent pixel definition patterns BPDL are spaced apart from each other at a gap.

In the embodiment of the present disclosure, the display substrate includes the plurality of pixel definition patterns BPDL, and the orthographic projection of at least one pixel definition pattern BPDL onto the base substrate at least partially overlaps with the orthographic projection of the boundary of a corresponding anode pattern Ano onto the base substrate. In this way, the pixel definition pattern BPDL is capable of forming the opening region on the anode pattern Ano, so as to ensure the normal display of the sub-pixel. In addition, the pixel definition layer is patterned to form the plurality of pixel definition patterns BPDL separate from each other, so as to improve a transmittance of the display substrate between the adjacent pixel definition patterns BPDL, thereby effectively improving the transmittance of the display substrate.

Referring to FIGS. 35, 36 and 37, in some embodiments, the orthographic projection of the pixel definition pattern BPDL onto the base substrate fully covers the orthographic projection of the boundary of the corresponding anode pattern Ano onto the base substrate.

Illustratively, the orthographic projection of the boundary of the anode pattern Ano onto the base substrate is located within the orthographic projection of the pixel definition pattern BPDL onto the base substrate, so that the pixel definition pattern BPDL can completely enclose an edge of the corresponding anode pattern, thereby ensuring the reliability of sub-pixel light emission while effectively improving the transmittance of the display substrate.

Referring to FIGS. 35, 36 and 37, in some embodiments, at least a portion of the orthographic projection of the pixel definition pattern BPDL onto the base substrate has an annular structure, and the annular structure is configured to define an opening region of a corresponding sub-pixel.

In the display substrate of the above-mentioned embodiment, when at least a portion of the orthographic projection of the pixel definition pattern BPDL onto the base substrate has the annular structure, it is able to, while ensuring that the pixel definition pattern BPDL shields the edge of the anode pattern Ano, reduce an area of the pixel definition pattern BPDL to the greatest extent, increase a distance between adjacent pixel definition patterns BPDL, and improve the transmittance of the display substrate in a better manner.

In some embodiments, at least a portion of the orthographic projection of the pixel definition pattern BPDL onto the base substrate has a circular-annular structure.

In the display substrate of the above-mentioned embodiment, when at least a portion of the orthographic projection of the pixel definition pattern BPDL onto the base substrate has a circular-annular structure, it is able to, while ensuring that the pixel definition pattern BPDL shields the edge of the anode pattern Ano, further reduce the area of the pixel definition pattern BPDL, increase the distance between adjacent pixel definition patterns BPDL, and improve the transmittance of the display substrate in a better manner.

With reference to FIGS. 35, 36 and 37, in some embodiments, the anode pattern Ano includes an anode main body Ano-1 and an anode connection member Ano-2 coupled to each other, and the anode connection member is coupled to a corresponding sub-pixel driving circuit. The pixel definition pattern BPDL includes a first sub-pattern BPDL-1 and a second sub-pattern BPDL-2 coupled to each other, an orthographic projection of the first sub-pattern BPDL-1 onto the base substrate has an annular structure, the orthographic projection of the first sub-pattern BPDL-1 onto the base substrate covers an orthographic projection of a boundary of a corresponding anode main body Ano-1 onto the base substrate, and an orthographic projection of the second sub-pattern BPDL-2 onto the base substrate covers an orthographic projection of a corresponding anode connection member Ano-2 onto the base substrate.

Illustratively, the anode main body Ano-1 and the anode connection member Ano-2 form a one-piece structure, an opening region is formed on the anode main body Ano-1, the anode connection member Ano-2 is coupled to the corresponding sub-pixel driving circuit, and the anode connection member Ano-2 transmits a received driving signal to the anode main body Ano-1 to realize the light-emitting function of the opening region.

Illustratively, the anode body part Ano-1 includes, but is not limited to, a circular anode body Ano-1.

Illustratively, the first sub-pattern BPDL-1 and the second sub-pattern BPDL-2 form a one-piece structure, and the first sub-pattern BPDL-1 has an annular structure and is capable of defining the opening region.

In the display substrate of the above-mentioned embodiment, when the orthographic projection of the first sub-pattern BPDL-1 onto the base substrate covers the orthographic projection of the boundary of the corresponding anode main body Ano-1 onto the base substrate, and the orthographic projection of the second sub-pattern BPDL-2 onto the base substrate covers the orthographic projection of the corresponding anode connection member Ano-2 onto the base substrate, it is able to, while ensuring that the pixel definition pattern BPDL shields the edge of the anode pattern Ano, reduce the area of the pixel definition pattern BPDL to the greatest extent, increase the distance between adjacent pixel definition patterns BPDL, and improve the transmittance of the display substrate in a better manner.

In some embodiments, the pixel definition pattern BPDL includes a black pixel delimiting pattern BPDL, and an orthographic projection of the pixel definition pattern onto the base substrate at least partially overlaps with an orthographic projection of a corresponding sub-pixel driving circuit onto the base substrate.

It should be noted that when the display substrate is applied in practical applications, light rays in the environment may enter the interior of the display substrate and be reflected by a non-transparent metal film layer in the display substrate and re-enter the environment, which seriously affects the visual experience of the user. Based on the above scheme, it is able for the pixel definition pattern BPDL to shield at least a portion of the corresponding sub-pixel driving circuit, so as to reduce the reflectivity of the non-transparent metal film layer in the sub-pixel driving circuit to ambient light, thereby effectively improving the user experience. In addition, the pixel definition pattern BPDL includes the black pixel definition pattern BPDL, so that the pixel definition pattern BPDL can absorb ambient light, thereby further reducing the reflection effect of the display substrate on the ambient light, and improving the user experience in a better manner.

In some embodiments, the sub-pixel driving circuit adopts, but not limited to, a 7T1C structure, i.e., 7 transistors and 1 storage capacitor.

The sub-pixel driving circuit includes a first transistor T1, a second transistor T2, a third transistor T3, a fourth transistor T4, a fifth transistor T5, a sixth transistor T6, a seventh transistor T7 and a storage capacitor Cst. The first transistor T1 and the second transistor T2 are each an n-type metal oxide semiconductor (NMOS) transistor, the third transistor T3, the fourth transistor T4, the fifth transistor T5, the sixth transistor T6, and the seventh transistor T7 are each a p-type metal oxide semiconductor (PMOS) transistors.

The display substrate further includes a power source line VDD, a light-emission control signal line EM, a data line Data, a first scanning line Gate_P, a second scanning line Gate_N, a reset signal line Reset_N and an initialization signal line Vinit.

A gate electrode of the first transistor T1 is coupled to the corresponding reset signal line Reset_N, a first electrode of the first transistor T1 is coupled to the initialization signal line Vinit, and a second electrode of the first transistor T1 is coupled to a gate electrode of the third transistor T3.

A gate electrode of the second transistor T2 is coupled to the corresponding second scanning line Gate_N, a first electrode of the second transistor T2 is coupled to the second electrode of the third transistor T3, and a second electrode of the second transistor T2 is coupled to the gate electrode of the third transistor T3.

A gate electrode of the fourth transistor T4 is coupled to the corresponding first scanning line Gate_P, a first electrode of the fourth transistor T4 is coupled to the corresponding data line Data, and a second electrode of the fourth transistor T4 is coupled to a first electrode of the third transistor T3.

A gate electrode of the fifth transistor T5 is coupled to the corresponding light-emission control signal line EM, a first electrode of the fifth transistor T5 is coupled to the power source line VDD, and a second electrode of the fifth transistor T5 is coupled to a first electrode of the third transistor T3.

A gate electrode of the sixth transistor T6 is coupled to a corresponding the light-emission control signal line EM, a first electrode of the sixth transistor T6 is coupled to a second electrode of the third transistor T3, a second electrode of the sixth transistor T6 is coupled to an anode pattern of a corresponding light-emitting element, and a cathode connected to the light-emitting element receives a power source signal VSS.

A gate electrode of the seventh transistor T7 is coupled to the corresponding first scanning line Gate_P, a first electrode of the seventh transistor T7 is coupled to the initialization signal line Vinit, and a second electrode of the seventh transistor T7 is coupled to the anode pattern of the corresponding light-emitting element.

Illustratively, the operation of the sub-pixel driving circuit includes the following stages.

At a first stage, a high-level signal is applied to the light-emission control signal line EM, the first scanning line Gate_P, a low-level signal is applied to the reset signal line Reset_N and the second scanning line Gate_N, the first transistor T1, the second transistor T2, the fourth transistor T4, the fifth transistor T5, the sixth transistor T6 and the seventh transistor T7 are not turned on, and a power source signal from the power source line VDD is written into the storage capacitor Cst.

At a second stage, a high-level signal is applied to the light-emission control signal line EM, the reset signal line Reset_N and the first scanning line Gate_P, a low-level signal is applied to the second scanning line Gate_N, the second transistor T2, the fourth transistor T4, the fifth transistor T5, the sixth transistor T6 and the seventh transistor T7 are not turned on, and a initialization signal from the initialization signal line Vinit is written into the storage capacitor Cst.

At a third stage, a high-level signal is applied to the light-emission control signal line EM, the second scanning line Gate_N, a low-level signal is applied to the first scanning line Gate_P and the reset signal line Reset_N, the first transistor T1, the fifth transistor T5, the sixth transistor T6 and the seventh transistor T7 are not turned on, the light-emitting element is initialized, and a power source signal from the power source line VDD is written into the storage capacitor Cst.

At a fourth stage, a high-level signal is applied to the light-emission control signal line EM and the first scanning line Gate_P, a low-level signal is applied to the second scanning line Gate_N and the reset signal line Reset_N. and the first transistor T1, the second transistor T2, the fourth transistor T4, the fifth transistor T5, the sixth transistor T6 and the seventh transistor T7 are not turned on.

At a fifth stage, a low-level signal is applied to the light-emission control signal line EM, the reset signal line Reset_N and the second scanning line Gate_N, a low-level signal is applied to the first scanning line Gate_P, the first transistor T1 is not turned on, the second transistor T2 is not turned on, the fourth transistor T4 is not turned on, the seventh transistor T7 is not turned on, and other transistors are turned on, and the light-emitting element emits light.

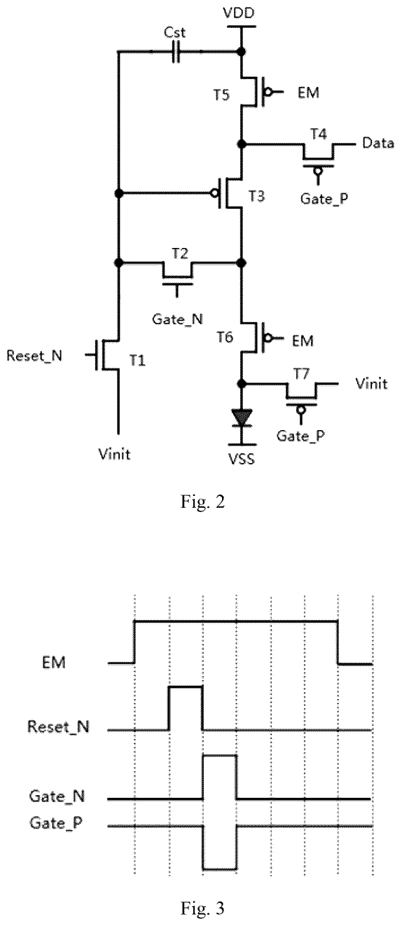

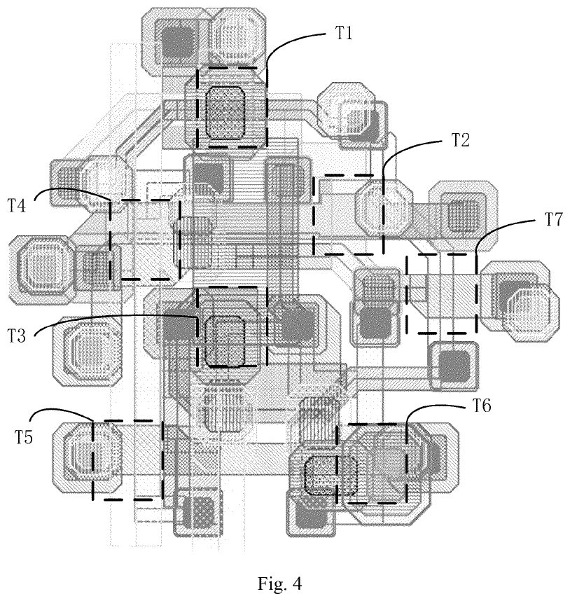

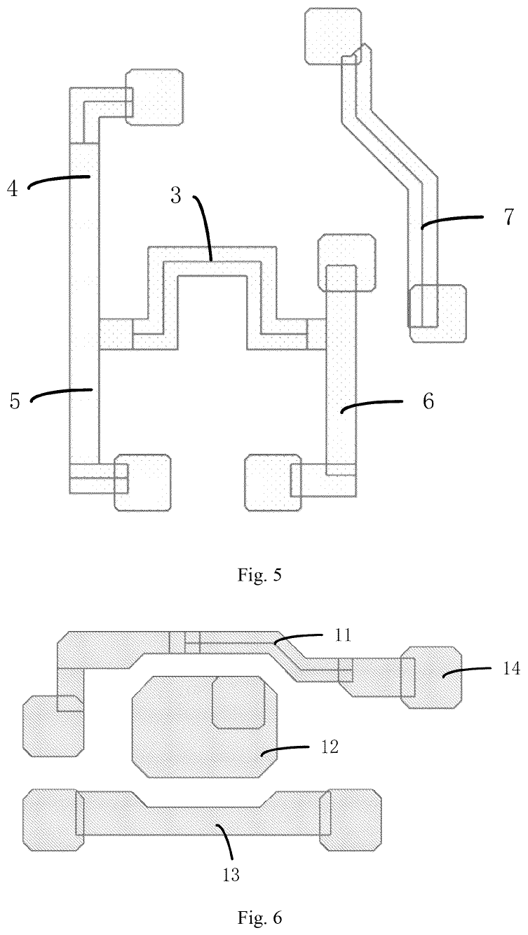

FIG. 4 shows the layout of the sub-pixel driving circuit in FIG. 2, in which each dashed box region denotes a transistor. FIGS. 5 to 34 are schematic views showing respective film layer of the sub-pixel driving circuit in FIG. 4 and structures of partial film layers laminated one on another. Illustratively, as shown in FIGS. 4 to 34, part of a process for forming the sub-pixel driving circuit is as follows.

A polysilicon layer, namely, an active layer, is deposited and then patterned to form a structure as shown in FIG. 5, including a third channel line 3, a fourth channel line 4, a fifth channel line 5, a sixth channel line 6 and a seventh channel line 7. The third channel line 3 is used for forming the T3, the fourth channel line 4 is used for forming the T4, the fifth channel line 5 is used for forming the T5, the sixth channel line 6 is used for forming the T6 and the seventh channel line 7 is used for forming the T7.

A first gate metal layer is deposited and patterned to form a structure as shown in FIG. 6, including a third gate line 11, a first electrode plate 12 and a sixth gate line 13. FIG. 7 is a schematic view showing a case where the first gate metal layer is superimposed on the polysilicon layer, T4 is formed where the third gate line 11 overlaps the fourth channel line 4, T7 is formed where the third gate line 11 overlaps the seventh channel line 7, and the third gate line 11 serves as top gate electrodes of T4 and T7. The first electrode plate 12 is used to form an electrode plate of the capacitor of FIG. 2, and T3 is formed where the first electrode plate 12 overlaps the third channel line 3. T5 is formed where the sixth gate line 13 overlaps the fifth channel line 5. T6 is formed where the sixth gate line 13 overlaps the sixth channel line, and the sixth gate line 13 is used to form top gate electrodes of T5 and T6. A first contact pad 14 is provided at an end of the third gate line 11.

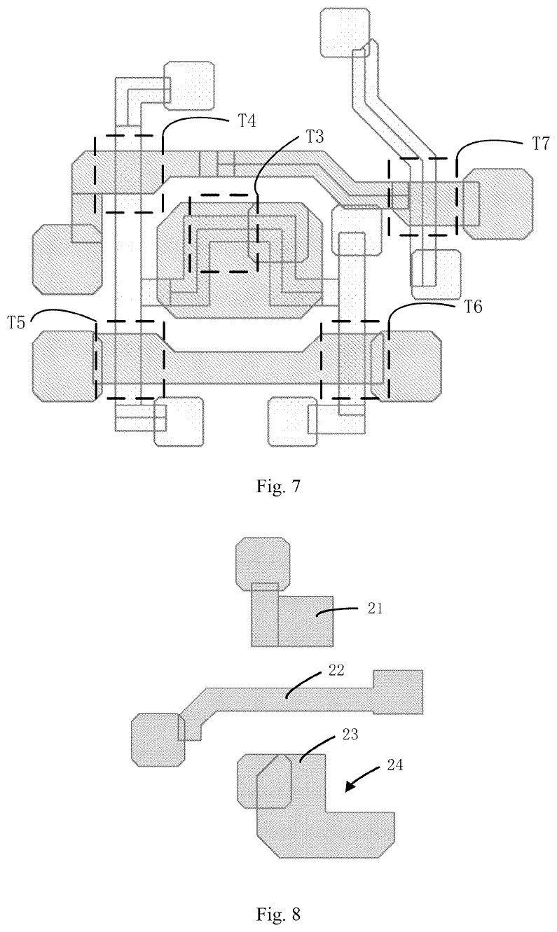

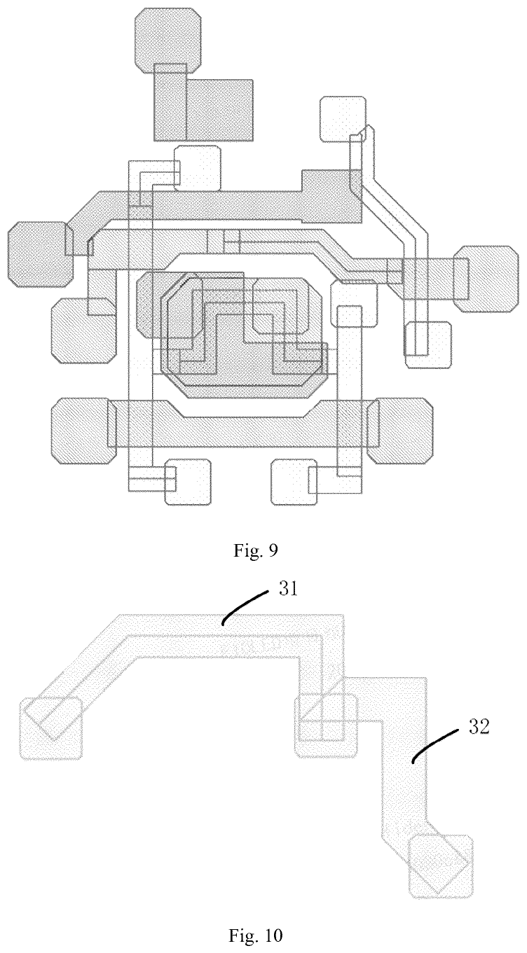

A second gate metal layer is deposited and then patterned to form a structure as shown in FIG. 8, including a first gate line 21, a fourth gate line 22 and a second electrode plate 23. The second electrode plate has an unfilled corner structure 24. The first gate line 21 is used to form a bottom gate electrode of T1, the fourth gate line 22 is used to form a bottom gate electrode of T2, and the second electrode plate 23 forms the capacitor Cst together with the first electrode plate 12. FIG. 9 is a schematic view showing a structure after the second gate metal layer is superimposed on the basis of FIG. 7.

A metal oxide layer is deposited and patterned to form a structure as shown in FIG. 10, including a first channel line 31 and a second channel line 32. The first channel line 31 is used for forming T1 and the second channel line 32 is used for forming T2. The first channel line 31 is connected to the second channel line 32. FIG. 11 is a schematic view showing a structure after a low temperature polycrystalline oxide layer is superimposed on the basis of FIG. 9.

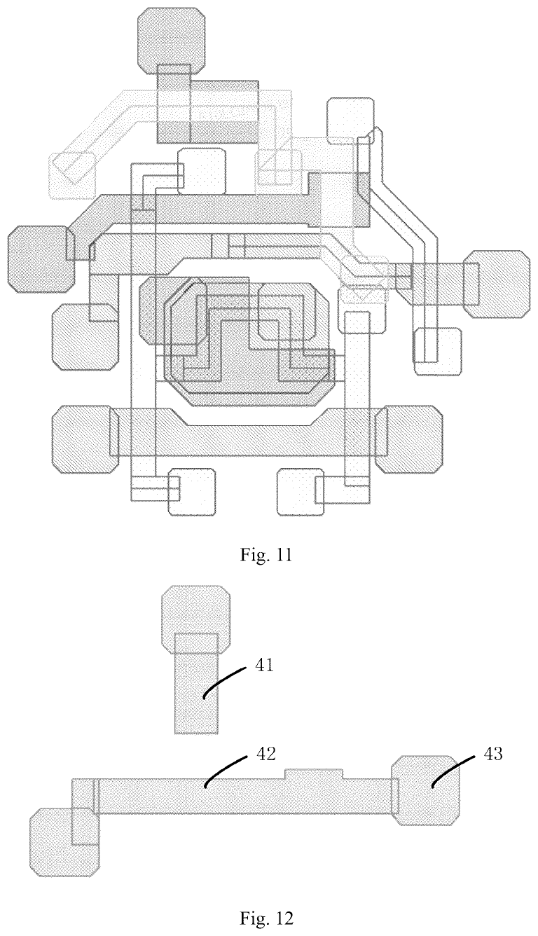

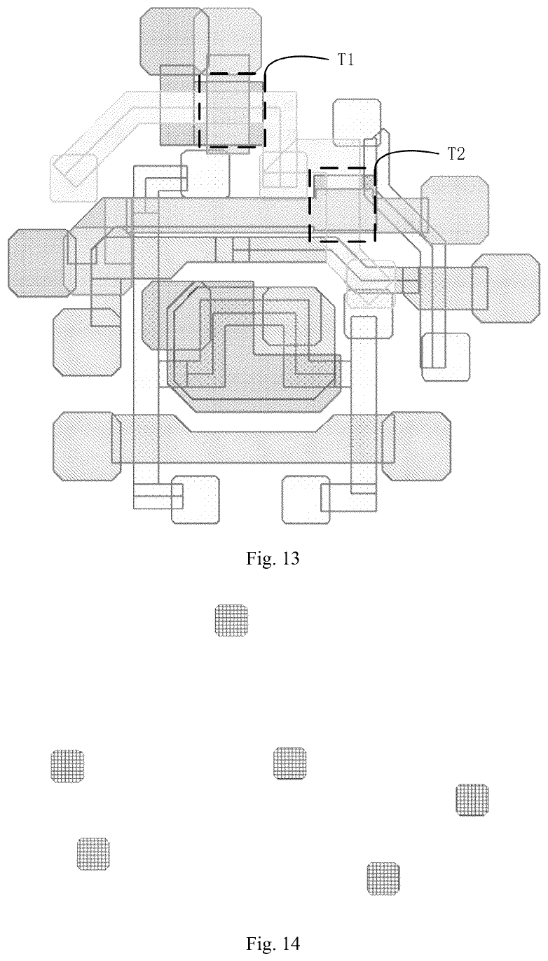

A third gate metal layer is deposited and patterned to form a structure shown in FIG. 12, including a second gate line 41 and a fifth gate line 42. The second gate line 41 is used for forming a top gate electrode of T1, and the fifth gate line 42 is used for forming a top gate electrode of T2. A second contact pad 43 is provided at an end of the fifth gate line. FIG. 13 is a schematic view showing a structure after the third gate metal layer is superimposed on the basis of FIG. 11.

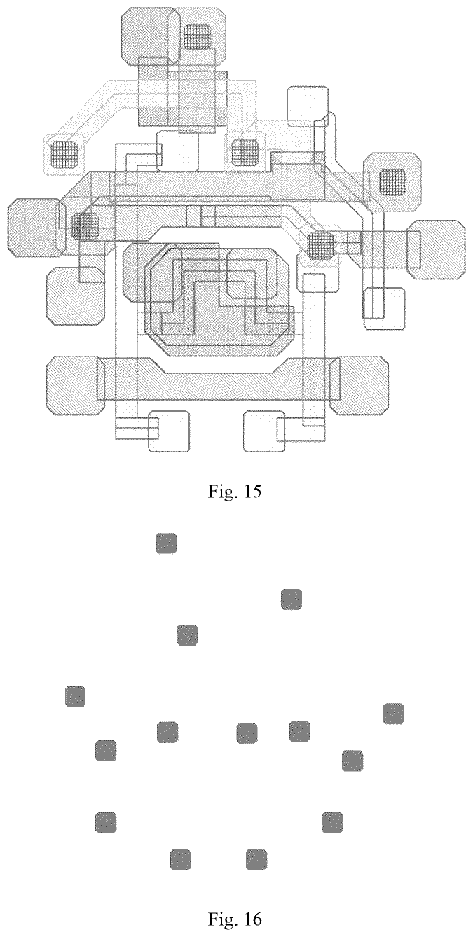

A first Inter Layer Dielectric (ILD) layer, i.e., a first interlayer insulating layer, is deposited. FIG. 14 is a schematic view showing a mask of the first ILD layer, and FIG. 15 is a schematic view showing a structure after the first ILD layer is superimposed on the basis of FIG. 13, and shows one or more via-holes formed in the first ILD layer.

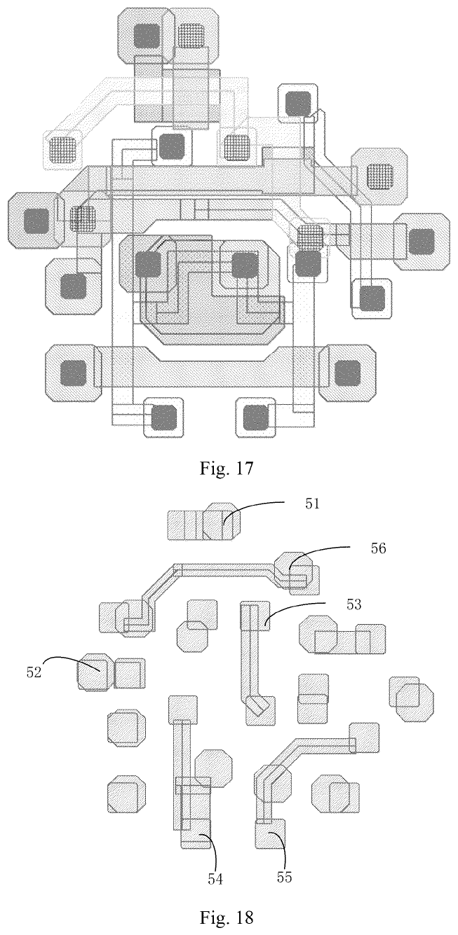

A second ILD layer, i.e., a second interlayer insulating layer, is deposited. FIG. 16 is a schematic view showing a mask of the second ILD layer, and FIG. 17 is a schematic view showing a structure after the second ILD layer is superimposed on the basis of FIG. 15, and shows one or more via-holes formed in the second ILD layer.

A first source/drain metal layer is deposited. FIG. 18 is a view showing the first source/drain metal layer, the first source/drain metal layer includes a first contact line 51, and the first contact line 51 is connected to the first gate line 21 and the second gate line 41 through via-holes formed in the first ILD layer and the second ILD layer.

The first source/drain metal layer further includes a non-transparent initialization portion 56 of the initialization signal line Vinit, and the non-transparent initialization portion 56 is connected to the first channel line 31 and the seventh channel line 7 through via-holes formed in the first ILD layer and the second ILD layer.

The first source/drain metal layer further includes a second contact line 52, and the second contact line 52 is connected to the fourth gate line 22 and the fifth gate line 42 through via-holes formed in the first ILD layer and the second ILD layer.

The first source/drain metal layer further includes a third contact line 53, one end of the third contact line 53 passes through the unfilled corner structure 24 after passing through via-holes formed in the first ILD layer and the second ILD layer and is connected to the first electrode plate 12, and the other end of the third contact line 53 is connected to the first channel line 31 and the second channel line 32 through via-holes formed in the first ILD layer and the second ILD layer.

The first source/drain metal layer further includes a fourth contact line 54, one end of the fourth contact line 54 is connected to the fifth channel line 5, and the other end thereof is connected to the second electrode plate 23.

The first source/drain metal layer further includes a fifth contact line 55 connected to the sixth channel line 6 and the seventh channel line 7.

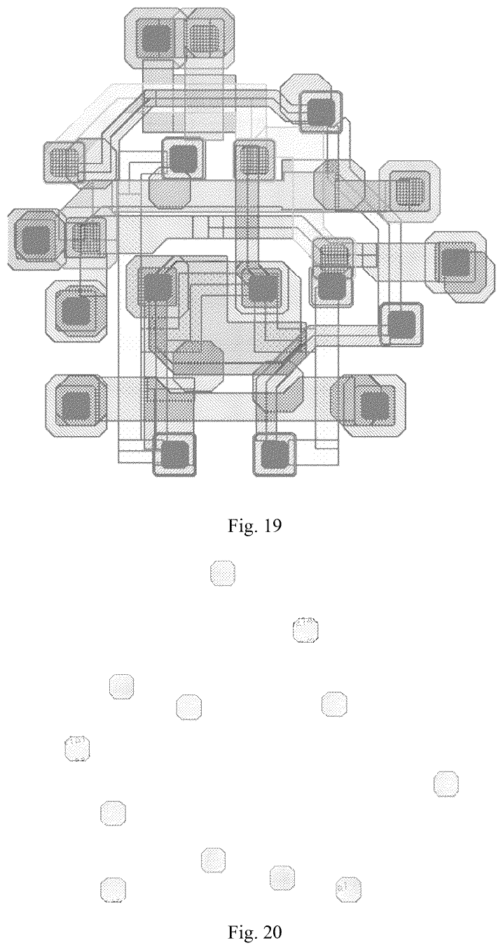

FIG. 19 is a schematic view showing a structure after the first source/drain metal layer is superimposed on the basis of FIG. 17.

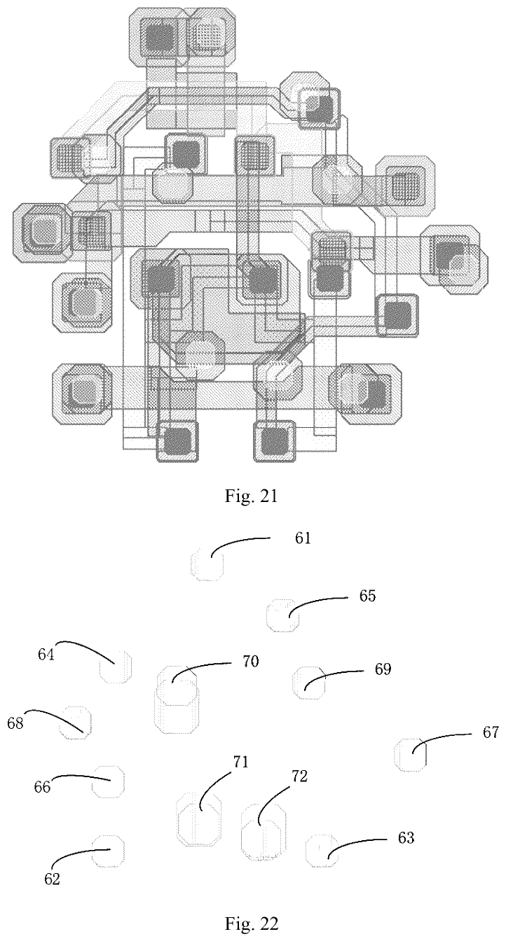

A passivation layer is deposited. FIG. 20 is a schematic view showing a mask of the passivation layer, and FIG. 21 is a schematic view showing a structure after the passivation layer is superimposed on the basis of FIG. 19, and shows one or more via-holes formed in the passivation layer.

A first ITO layer, i.e., a first transparent conductive layer, is deposited. The first ITO layer includes a first connection line and a contact structure for the first connection line and the sub-pixel driving circuit. FIG. 22 shows one or more contact structures in the first ITO layer.

The first ITO layer includes a first contact structure 61 connected to the first contact line 51, the first contact structure 61 and at least one first connection line form a one-piece structure.

The first ITO layer further includes a second contact structure 62 located at one end of the sixth gate line 13, and a third contact structure 63 located at the other end of the sixth gate line 13. Another first connection line form a one-piece structure with the second contact structure 62 and the third contact structure 63, and the another first connecting line is connected to the sixth gate line 13 through the second contact structure 62 and the third contact structure 63.

The first ITO layer further includes a fourth contact structure 64 located at one end of the initialization signal line and a fifth contact structure 65 located at the other end of the initialization signal line, and one first connecting line is connected to the initialization signal line through the fourth contact structure 64 and the fifth contact structure 65.

The first ITO layer further includes a sixth contact structure 66 located at one end of the third gate line 11 and a seventh contact structure 67 located at the other end of the third gate line 11, and one first connection is connected to the third gate line 11 through the sixth contact structure 66 and the seventh contact structure 67.

The first ITO layer further includes an eighth contact structure 68 at one end of the fifth gate line 42 and a ninth contact structure 69 at the other end of the fifth gate line 42, and one first connection is connected to the fifth gate line 42 through the eighth contact structure 68 and the ninth contact structure 69.

The first ITO layer further includes a tenth contact structure 70 connected to the T4 channel line.

The first ITO layer further includes an eleventh contact structure 71 connected to the fourth contact line 54.

The first ITO layer further includes a twelfth contact structure 72 connected to the fifth contact line 55.

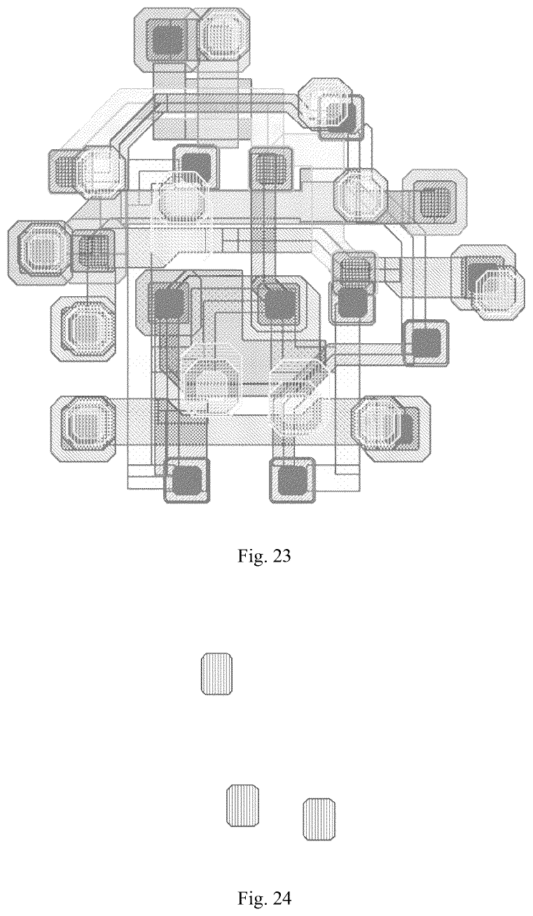

FIG. 23 is a schematic view showing a structure after the first ITO layer is superimposed on the basis of FIG. 21.

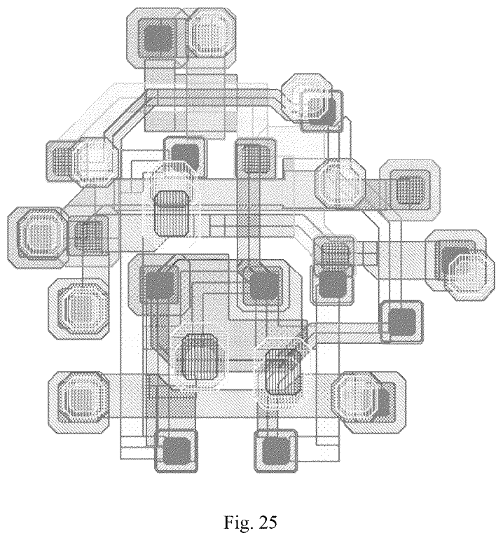

A first planarization layer is deposited. FIG. 24 is a view showing a mask of the first planarization layer, and FIG. 25 is a schematic view showing a structure after the first planarization layer is superimposed on the basis of FIG. 23, and shows one or more via-holes formed in the first planarization layer.

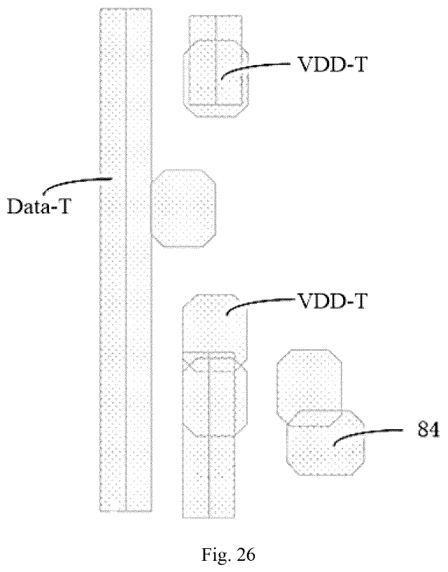

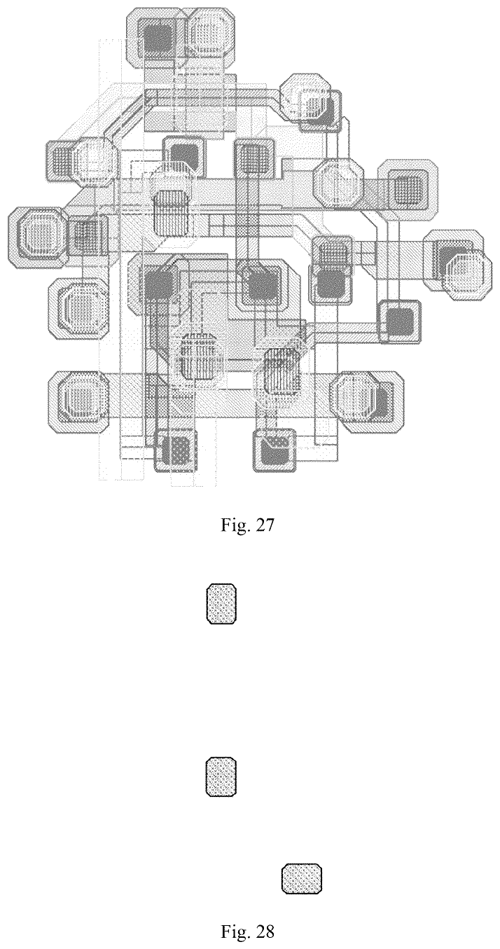

A second ITO layer, i.e., a second transparent conductive layer, is deposited. The second ITO layer includes a transparent power source portion VDD-T, a transparent data line Data-T and a connection structure 84. The transparent data line Data-T is connected to the tenth contact structure 70, a first end of the transparent power source portion VDD-T is connected to the eleventh contact structure 71, and a second end of the transparent power source portion VDD-T is connected to the second source/drain metal layer. FIG. 26 shows the second ITO layer, and FIG. 27 a schematic view showing a structure after the second ITO layer is superimposed on the basis of FIG. 25.

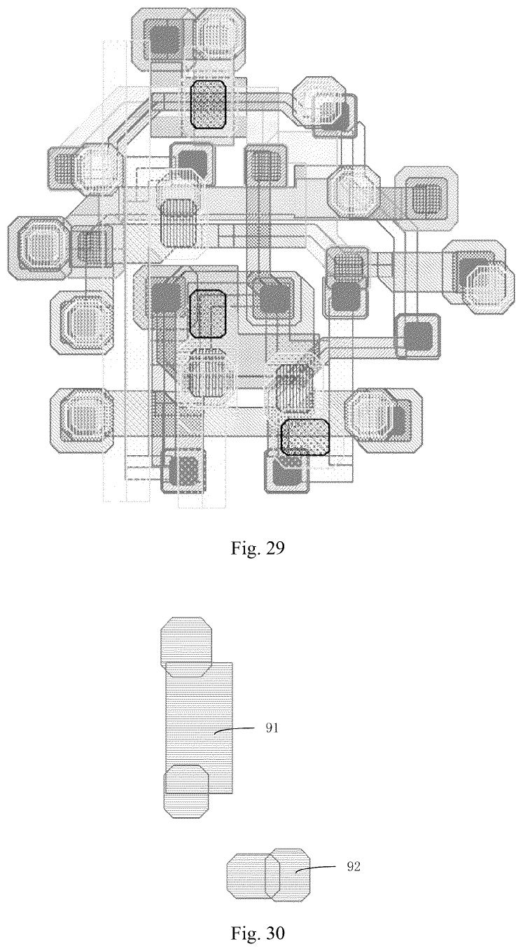

A second planarization layer is deposited. FIG. 28 is a schematic view showing a mask of the second planarization layer, and FIG. 29 is a schematic view showing a structure after the second planarization layer is superimposed on the basis of FIG. 27, and shows one or more via-holes formed in the second planarization layer.

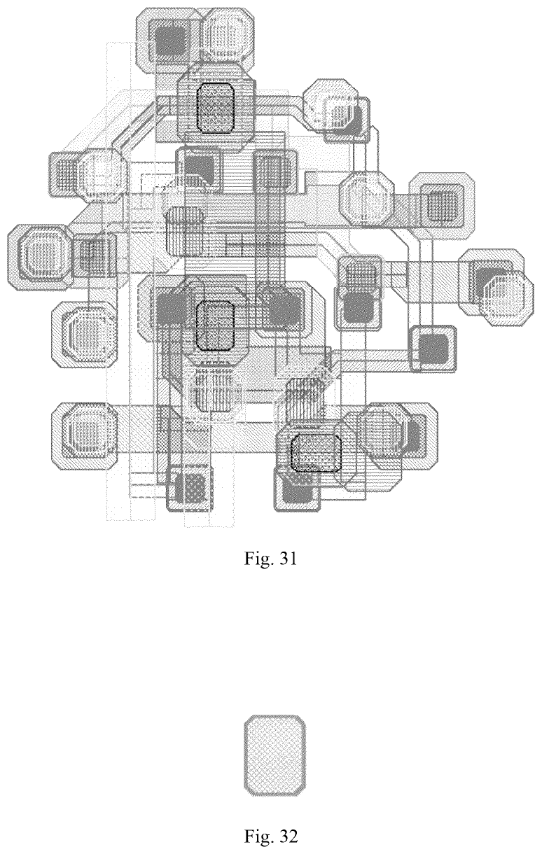

A second source/drain metal layer is deposited. FIG. 30 is a schematic view showing the second source/drain metal layer, which includes a connection member 91 and an anode adaptor structure 92. The connection member 91 is connected to a first end of one transparent power source portion VDD-T and another anode adaptor structure 92 at a second end of another transparent power source portion VDD-T adjacent to the one transparent power source portion VDD-T, and the anode adaptor structure 92 is connected to the connection structure 85 and the anode pattern. FIG. 31 is a schematic view showing a structure after the second source/drain metal layer is superimposed on the basis of FIG. 29.

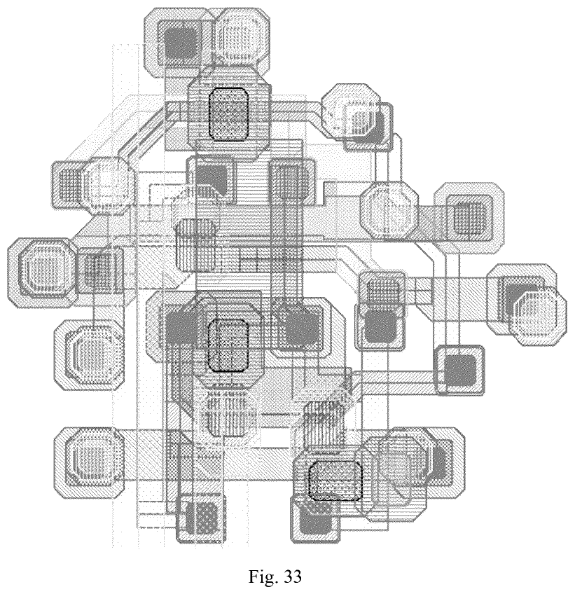

A third planarization layer is deposited. FIG. 32 is a view showing a mask of the third planarization layer, and FIG. 33 is a schematic view showing a structure after the third planarization layer is superimposed on the basis of FIG. 31.

In some embodiments, at least a portion of an orthographic projection of an outer boundary of the sub-pixel driving circuit onto the base substrate is located within the orthographic projection of the corresponding the pixel definition pattern BPDL onto the base substrate.

In some embodiments, the sub-pixel driving circuit includes a storage capacitor, the storage capacitor includes a first electrode plate and a second electrode plate arranged opposite to each other, and the first electrode plate is located between the second electrode plate and the base substrate. An orthographic projection of the second electrode plate onto the base substrate partially overlaps the orthographic projection of the pixel definition pattern BPDL onto the base substrate, and an orthographic projection of a portion of the second electrode plate onto the base substrate is surrounded by the orthographic projection of the pixel definition pattern BPDL onto the base substrate.

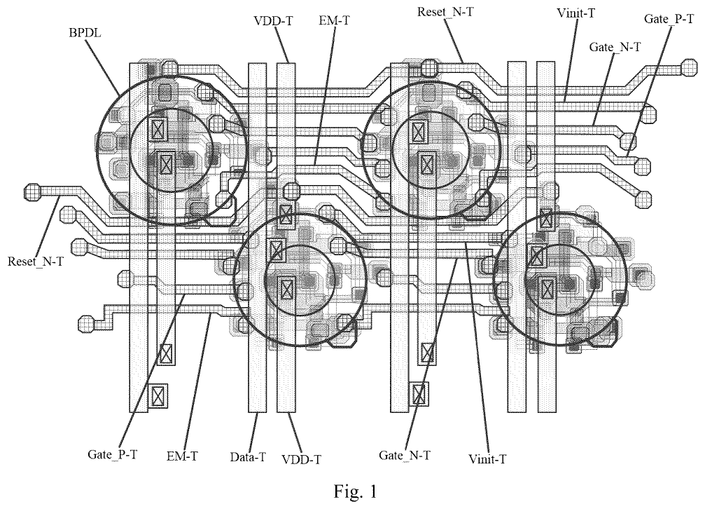

As shown in FIG. 1, in some embodiments, the display substrate further includes a transparent data line Data-T, and at least a portion of an orthographic projection of the transparent data line Data onto the base substrate is located between orthographic projections of adjacent pixel definition patterns BPDL onto the base substrate.

Illustratively, the transparent data line Data-T is formed by using the second transparent metal layer. The second transparent metal layer is, but not limited to, made of an indium tin oxide material.

Illustratively, the transparent data line Data-T includes at least a portion extending in the second direction.

Illustratively, the display substrate includes a plurality of transparent data lines Data-T arranged along the first direction and at least one transparent data line Data-T is coupled to sub-pixel driving circuits in a corresponding column.

In the display substrate of the above-mentioned embodiment, when at least a portion of the orthographic projection of the transparent data line Data-T onto the base substrate is between the orthographic projections of the adjacent pixel definition patterns BPDL onto the base substrate, the transmittance of the display substrate between the adjacent pixel definition patterns BPDL is better improved.

As shown in FIG. 1, in some embodiments, the display substrate further includes a transparent reset signal line Reset_N-T, at least a portion of an orthographic projection of the transparent reset signal line Reset_N-T onto the base substrate is located between orthographic projections of adjacent pixel definition patterns BPDL onto the base substrate.

Illustratively, the transparent reset signal line Reset_N-T is formed by using the first transparent metal layer.

Illustratively, the transparent reset signal line Reset_N-T includes at least a portion extending in the first direction.

Illustratively, the display substrate includes a plurality of transparent reset signal lines Reset_N-T arranged along the second direction, and at least one transparent reset signal lines Reset_N-T is coupled to sub-pixel driving circuits in a corresponding row.

In the display substrate of the above-mentioned embodiment, when at least a portion of the orthographic projection of the transparent reset signal line Reset_N-T onto the base substrate is located between the orthographic projections of the adjacent pixel definition patterns BPDL onto the base substrate, the transmittance of the display substrate between the adjacent pixel definition patterns BPDL is better improved.

As shown in FIG. 1, in some embodiments, the display substrate includes an initialization signal line Vinit, the initialization signal line Vinit includes a transparent initialization portion Vinit-T, and at least a portion of an orthographic projection of the transparent initialization portion Vinit-T onto the base substrate is located between orthographic projections of adjacent pixel definition patterns BPDL onto the base substrate.

Illustratively, the transparent initialization portion Vinit-T is formed by using the first transparent metal layer.

Illustratively, the transparent initialization portion Vinit-T includes at least a portion extending in the first direction.

Illustratively, the display substrate includes a plurality of initialization signal lines Vinit arranged along the second direction, and at least one initialization signal line Vinit is coupled to sub-pixel driving circuits in a corresponding row.

In the display substrate of the above-mentioned embodiment, when at least a portion of the orthographic projection of the transparent initialization portion Vinit-T onto the base substrate is located between the orthographic projections of the adjacent pixel definition patterns BPDL onto the base substrate, the transmittance of the display substrate between the adjacent pixel definition patterns BPDL is better improved.

As shown in FIG. 1, in some embodiments, the sub-pixel driving circuit includes a data written-in transistor (namely, the fourth transistor T4), the display substrate includes a first scanning line Gate_P, a gate electrode of the data written-in transistor is coupled to a corresponding first scanning line Gate_P, the first scanning line Gate_P includes a first transparent scanning portion Gate_P-T, an orthographic projection of the first transparent scanning portion Gate_P-T onto the base substrate is located between orthographic projections of adjacent pixel definition patterns BPDL onto the base substrate.

Illustratively, the first transparent scanning portion Gate_P-T is formed by using the first transparent metal layer.

Illustratively, the first transparent scanning portion Gate_P-T includes at least a portion extending in the first direction.

Illustratively, the display substrate includes a plurality of first scanning lines Gate_P arranged along the second direction, and at least one first scanning lines Gate_P is coupled to sub-pixel driving circuits in a corresponding row.

In the display substrate of the above-mentioned embodiment, when at least a portion of the orthographic projection of the first transparent scanning portion Gate_P-T onto the base substrate is located between the orthographic projections of the adjacent pixel definition patterns BPDL onto the base substrate, the transmittance of the display substrate between the adjacent pixel definition patterns BPDL is better improved.

As shown in FIG. 1, in some embodiments, the sub-pixel driving circuit includes a compensation transistor (namely, the second transistor T2), the display substrate includes a second scanning line Gate_N, a gate electrode of the compensation transistor is coupled to a corresponding second scanning line Gate_N, the second scanning line Gate_N includes a second transparent scanning portion Gate_N-T, an orthographic projection of the second transparent scanning portion Gate_N-T onto the base substrate is located between orthographic projections of adjacent pixel definition patterns BPDL onto the base substrate.

Illustratively, the second transparent scanning portion Gate_N-T is formed by using the first transparent metal layer.

Illustratively, the second transparent scanning portion Gate_N-T includes at least a portion extending in the first direction.

Illustratively, the display substrate includes a plurality of second scanning lines Gate_N arranged along the second direction, and at least one second scanning line Gate_N is coupled to sub-pixel driving circuits in a corresponding row.

In the display substrate of the above-mentioned embodiment, when at least a portion of the orthographic projection of the second transparent scanning portion Gate_N-T onto the base substrate is between the orthographic projections of the adjacent pixel definition patterns BPDL onto the base substrate, the transmittance of the display substrate between the adjacent pixel definition patterns BPDL is better improved.

As shown in FIG. 1, in some embodiments, the display substrate includes a light-emission control signal line EM, the light-emission control signal line includes a transparent light-emission control portion EM-T, and at least a portion of an orthographic projection of the transparent light-emission control portion EM-T onto the base substrate is located between orthographic projections of adjacent pixel definition patterns BPDL onto the base substrate.

Illustratively, the transparent light-emission control portion EM-T is formed by using the first transparent metal layer.

Illustratively, the transparent light-emission control portion EM-T includes at least a portion extending in the first direction

Illustratively, the display substrate includes a plurality of light-emission control signal lines EM arranged along the second direction, at least one light-emission control signal line EM is coupled to sub-pixel driving circuits in a corresponding row.

In the display substrate of the above-mentioned embodiment, when at least a portion of the orthographic projection of the transparent light-emission control portion EM-T onto the base substrate is between the orthographic projections of the adjacent pixel definition patterns BPDL onto the base substrate, the transmittance of the display substrate between the adjacent pixel definition patterns BPDL is better improved.

As shown in FIG. 1, in some embodiments, the display substrate further includes a power source line VDD, the power source line VDD includes a transparent power source portion VDD-T, an orthographic projection of the transparent power source portion VDD-T onto the base substrate is between orthographic projections of adjacent pixel definition patterns BPDL onto the base substrate.

Illustratively, the transparent power source portion VDD-T is formed by using the second transparent metal layer.

Illustratively, the transparent power source portion VDD-T includes at least a portion extending in the second direction.

Illustratively, the display substrate includes a plurality of power source lines VDD arranged in the first direction, at least power source line VDD is coupled to sub-pixel driving circuits in a corresponding column.

In the display substrate of the above-mentioned embodiment, when at least a portion of the orthographic projection of the transparent power source portion VDD-T onto the base substrate is between the orthographic projections of the adjacent pixel definition patterns BPDL onto the base substrate, the transmittance of the display substrate between the adjacent pixel definition patterns BPDL is better improved.

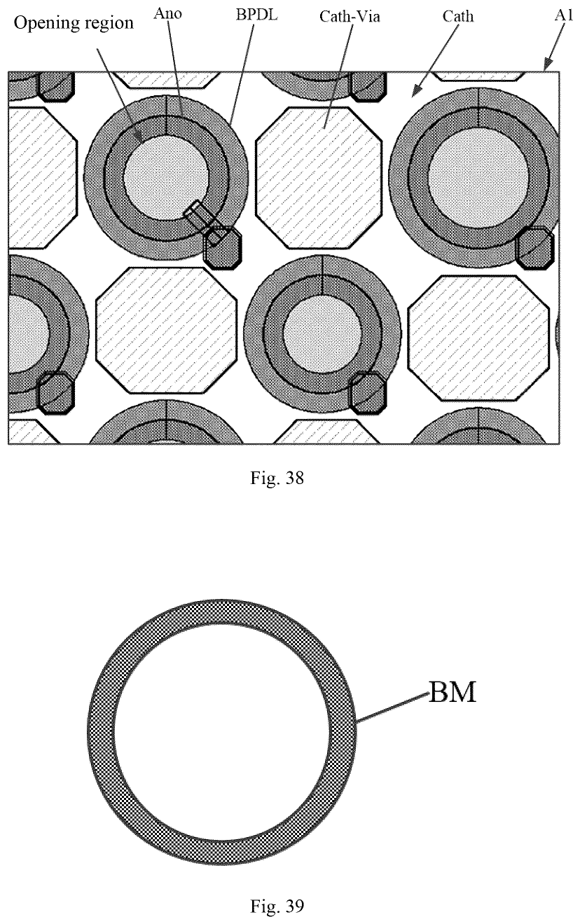

As shown in FIG. 38, in some embodiments, the display substrate further includes a cathode layer Cath located on a side of the light-emitting element away from the base substrate, the cathode layer Cath includes a plurality of cathode openings Cath-Via, and at least a portion of an orthographic projection of at least one cathode opening Cath-Via onto the base substrate is located between orthographic projections of adjacent pixel definition patterns BPDL onto the base substrate.

Illustratively, the cathode layer Cath is a whole-layer structure covering the display region and is a one-piece structure, and the plurality of cathode openings Cath-Via is spaced apart from each other on the cathode layer Cath, and the plurality of cathode openings Cath-Via is separate from each other.

Illustratively, the orthographic projection of the cathode opening Cath-Via onto the base substrate is fully between the orthographic projections of the adjacent pixel definition patterns BPDL onto the base substrate.

Illustratively, the cathode opening Cath-Via is, but not limited to, of a polygon, such as octagonal, shape. In this way, it is able to increase an opening area of the cathode opening Cath-Via as much as possible in a limited layout space while ensuring normal function of the cathode.

In the display substrate of the above-mentioned embodiment, when the cathode layer Cath includes multiple cathode openings Cath-Via, it is able not only to improve the transmittance of the display substrate, but also to reduce the reflection of ambient light by the cathode layer Cath, thereby reducing the reflectivity of the display substrate.

In some embodiments, the orthographic projection of the cathode opening Cath-Via onto the base substrate is located between orthographic projections of adjacent pixel definition patterns BPDL onto the base substrate.

As shown in FIG. 38, in some embodiments, the plurality of cathode openings Cath-Via is distributed in an array form.

When the plurality of cathode openings Cath-Via is distributed in an array form, it is able to improve the display uniformity of the display substrate.

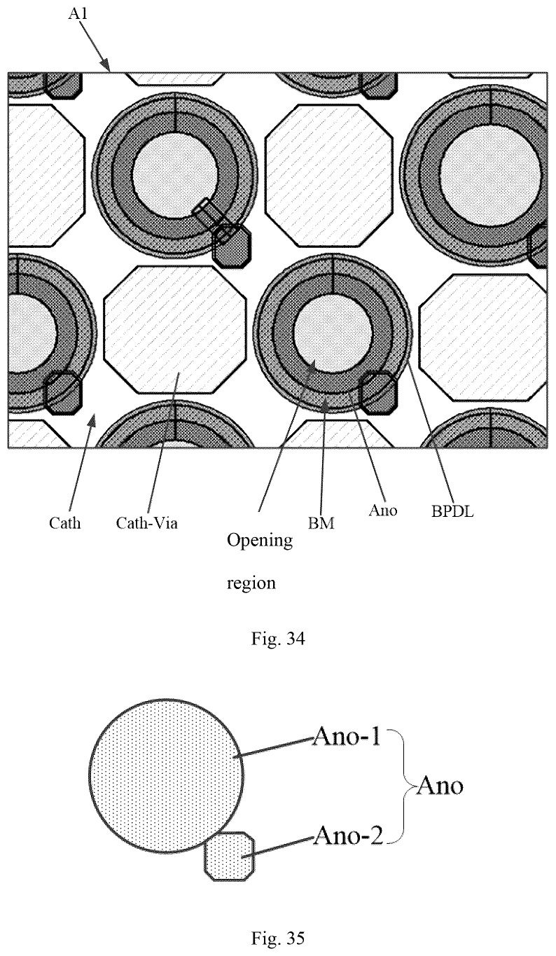

As shown in FIGS. 39 and 34, in some embodiments, the display substrate further includes an encapsulation layer and a plurality of black matrix patterns BM, the encapsulation layer is located between the plurality of black matrix patterns BM and the base substrate, an orthographic projection of at least one black matrix pattern BM onto the base substrate at least partially overlaps an orthographic projection of a corresponding pixel definition pattern BPDL onto the base substrate.

Illustratively, the display substrate further includes a plurality of color film patterns and a plurality of black matrix patterns (BM), the plurality of color film patterns and the plurality of black matrix patterns (BM) are located on a side of the encapsulation layer away from the base substrate, the color film patterns and the black matrix patterns (BM) are located on a same surface, and one black matrix pattern (BM) is arranged between adjacent color film patterns. Illustratively, the color film patterns include, but not limited to, a red color film pattern, a green color film pattern and a blue color film pattern.

Illustratively, the display substrate further includes a touch structure located on a side of the encapsulation layer away from the base substrate, and the plurality of color film patterns and the plurality of black matrix patterns BM are located on a side of the touch structure away from the base substrate. The display substrate further includes a planarization layer and a cover plate, and the planarization layer is located between the cover plate and the black matrix patterns BM as well as the color film patterns.

Illustratively, the plurality of black matrix patterns BM is distributed in an array form, and adjacent black matrix patterns BM are spaced apart from each other at a gap.

In the display substrate of the above-mentioned embodiment, the display substrate further includes the black matrix patterns BM and the color film patterns, so that the display substrate adopts COE (Color On Encapsulation) technology, thereby well improving the display contrast of the display substrate.

In the display substrate of the above-mentioned embodiment, the orthographic projection of the black matrix pattern BM onto the base substrate at least partially overlaps with the orthographic projection of the corresponding pixel defining layer onto the base substrate, so that not only is the opening region in the display substrate prevented from being shield by the black matrix pattern BM, but also the black matrix pattern BM can absorb ambient light, thereby ensuring the opening rate and light transmittance of the display substrate in a better manner.

As shown in FIGS. 39 and 34, in some embodiments, the orthographic projection of the black matrix pattern BM onto the base substrate includes an annular structure, an orthographic projection of an inner boundary of the black matrix pattern BM onto the base substrate surrounds an orthographic projection of an inner boundary of the corresponding pixel definition pattern BPDL onto the base substrate.

Illustratively, the orthographic projection of the black matrix pattern BM onto the base substrate is circular.

Due to the above-mentioned arrangement, not only is the opening region in the display substrate prevented from being shield by the black matrix pattern BM, but also the black matrix pattern BM can absorb ambient light, thereby ensuring the opening rate and light transmittance of the display substrate in a better manner.

As shown in FIGS. 39 and 34, in some embodiments, an orthographic projection of an outer boundary of the pixel definition pattern BPDL onto the base substrate surrounds an orthographic projection of the corresponding black matrix pattern BM onto the base substrate.

When the orthographic projection of the black matrix pattern BM onto the base substrate is fully located within the orthographic projection of the pixel definition pattern BPDL onto the base substrate, it is able to prevent the light transmittance of the display substrate from being affected adversely by the black matrix pattern BM, thereby effectively ensuring the light transmittance of the display substrate.

As shown in FIG. 40, in some embodiments, the display substrate includes a first display region A1 and a second display region A2, the second display region A2 is located on at least one side of the first display region A1, a light transmittance of the first display region A1 is greater than a light transmittance of the second display region A2, and the plurality of pixel definition patterns is located at the first display region A1.

Illustratively, the first display region A1 is used to receive a photographing structure.

Illustratively, a resolution of the first display region A1 is larger than a resolution of the second display region A2.

Illustratively, the resolution of the first display region A1 is smaller than the resolution of the second display region A2.

Illustratively, the resolution of the first display region A1 is equal to the resolution of the second display region A2.

Illustratively, a pixel density of the first display region A1 is larger than a pixel density of the second display region A2.

Illustratively, the pixel density of the first display region A1 is smaller than the pixel density of the second display region A2.

Illustratively, the pixel density of the first display region A1 is equal to the pixel density of the second display region A2.

Illustratively, the second display region A2 surrounds the first display region A1, or at least a portion of the second display region A2 is located on one side of the first display region A1. However, the present disclosure is limited thereto.

Illustratively, the second display region A2 is a normal display region without a photographing structure.

Illustratively, the first display region A1 includes a circular display region, a square display region, etc.

In the display substrate of the above-mentioned embodiment, the first display region A1 includes the photographing structure and the plurality of pixel definition patterns BPDL, it is able to effectively improve the transmittance of the first display region A1, thereby to improve the display quality of the display substrate.

In some embodiments, the second display region A2 includes the plurality of pixel definition patterns BPDL.

Illustratively, in the first display region A1 and the second display region A2, layouts of pixel definition layers are the same manner, i.e., the first display region A1 and the second display region A2 each includes the plurality of pixel definition patterns BPDL.

When the second display region A2 includes the plurality of pixel definition patterns BPDL, it is able to effectively improve the transmittance of the second display region A2, thereby to improve the display quality of the display substrate.

FIG. 40 is a schematic view showing a display substrate in at least one embodiment of the present disclosure. In some examples, as shown in FIG. 40, the display substrate may include a display region AA and a peripheral region BB surrounding a periphery of the display region AA. The display region AA of the display substrate may include a first display region A1 and a second display region A2 located on at least one side of the first display region A1. For example, the second display region A2 may surround the first display region A1. The first display region A1 may be located at a top middle position of the display region AA. However, the present disclosure is not limited thereto. For example, the first display region A1 may be located at other positions such as a top-left corner or a top-right corner of the display region AA.

In some examples, as shown in FIG. 40, the display region AA may has a rectangular shape, such as a rectangular shape with rounded corners. The first display region A1 may has a circular or elliptical shape. However, the present disclosure is not limited thereto. For example, the shape of the first display region may be rectangular, pentagonal, hexagonal, or the like.

In some examples, as shown in FIG. 40, the first display region A1 may be a light-transmitting display region, which may also be referred to as a FDC (Full Display With Camera) region. The second display region A2 may be a non-light-transmitting display region, which may also be referred to as a normal display region. The light transmittance of the first display region A1 is greater than the light transmittance of the second display region A2. For example, an orthographic projection of hardware such as a photosensitive sensor (e.g., camera, infrared sensor) onto the display substrate may be located within the first display region A1 of the display substrate. In some examples, the first display region A1 may be of a circular shape, and a size of an orthographic projection of the photosensitive sensor onto the display substrate may be less than or equal to a size of the first display region A1. However, the present disclosure is not limited thereto. In other examples, the first display region may has a rectangular shape and the size of the orthographic projection of the photosensitive sensor onto the display substrate may be less than or equal to a size of the inscribed circle of the first display region.

In some examples, the display region AA may include at least a plurality of pixel units arranged regularly, a plurality of gate lines (e.g., including: a scanning line, a reset signal line, a light-emission control signal line) extending in the first direction X, and a plurality of data lines extending in the second direction Y and a power source line. The first direction X and the second direction Y may on a same plane, and the first direction X crosses the second direction Y, for example, the first direction X may be perpendicular to the second direction Y.

In some examples, one pixel unit of display region AA may include three sub-pixels, which may be a red sub-pixel, a green sub-pixel and a blue sub-pixel. However, the present disclosure is not limited thereto. In some examples, one pixel unit may include four sub-pixels, which may be a red sub-pixel, a green sub-pixel, a blue sub-pixel and a white sub-pixel.

In some examples, at least one sub-pixel may include a sub-pixel driving circuit and a light-emitting element. The sub-pixel driving circuit may be configured to drive the connected light-emitting element. For example, the sub-pixel driving circuit may be configured to provide a driving current, so as to drive the light-emitting element to emit light. The sub-pixel driving circuit may include a plurality of transistors and at least one capacitor, for example, the sub-pixel driving circuit may have a 3T1C structure, an 8T1C structure, a 7T1C structure, or a 8T1C structure. T in the above-mentioned sub-pixel driving circuit refers to a thin film transistor, C refers to a capacitor, and the number before T represents the quantity of thin film transistors in the circuit, and the number before C represents the quantity of capacitors in the circuit.

In some examples, the light-emitting element may be a light-emitting diode (LED), an organic light-emitting diode (OLED), a quantum dot light-emitting diode (QLED), a micro-LED (including mini-LED or micro-LED) and the like. For example, the light-emitting element may be an OLED, and the light-emitting element may, under the driving of its corresponding pixel circuit, emit red light, green light, blue light, or white light, etc. The color of light emitted by the light-emitting element may be determined according to the practical need.

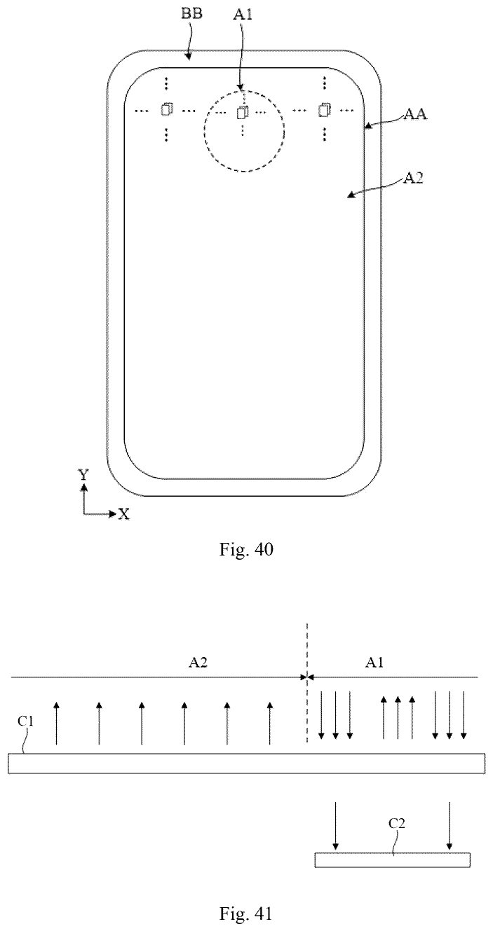

FIG. 41 is a schematic view showing a display device in at least one embodiment of the present disclosure. As shown in FIG. 41, the present embodiment provides a display device including a display substrate C1 and a photosensitive sensor C2 located on a light-exiting side of a display structure layer away from the display substrate C1. An orthographic projection of the photosensitive sensor C2 onto the display substrate C1 overlaps the first display region A1.

In some examples, the display substrate C1 may be a flexible OLED display substrate, a QLED display substrate, a Micro-LED display substrate or a Mini-LED display substrate. The display device may be any product or member having a display function, e.g., an OLED display, a mobile phone, a tablet computer, a television, a display, a laptop computer, a digital photo frame, and a navigator. However, the embodiments of the present disclosure are not limited thereto.

Embodiments of the present disclosure further provide a display device including the display substrate in the above embodiments, and a sensor located on a non-display side of the display substrate, an orthographic projection of the sensor onto the display substrate overlaps with the first display region of the display substrate.

The sensor includes a webcam, a photosensitive element, a photosensitive device, a sensor, an optical member, an optical device, a camera, a photosensitive assembly, an optical sensor, a sensing module, a flash, a proximity sensor, an illumination sensor.

It is to be noted that the display device may be any product or member having a display function, such as a television, a display, a digital photo frame, a mobile phone, a tablet computer, and etc. The display device further includes a flexible circuit board, a printed circuit board and a backplane.

In the above embodiments of the present disclosure, the display substrate includes the plurality of pixel definition patterns BPDL, the orthographic projection of at least one pixel definition pattern BPDL onto the base substrate at least partially overlaps with the orthographic projection of the boundary of the corresponding anode pattern Ano onto the base substrate. In this way, the pixel definition pattern BPDL is capable of forming the opening region on the anode pattern Ano, so as to ensure the normal display of the sub-pixel. In addition, the pixel definition layer is patterned to form the plurality of pixel definition patterns BPDL separate from each other, so as to improve the transmittance of the display substrate between the adjacent pixel definition patterns BPDL, thereby effectively improving the transmittance of the display substrate.

The display device in the embodiments of the present disclosure also has the above-mentioned beneficial effects when including the above-mentioned display substrate, and will not be described in detail herein.

It is to be noted that the signal line extending in the X direction means that the signal line includes a main part and a secondary part connected to the main part, the main part being a line, a line segment or a bar-shaped body, the main part extends in the X-direction, and a length of the main part extending in the X-direction is greater than a length of the secondary part extending in another direction.

It should be appreciated that, the expression “at a same layer” refers to that the film layers are arranged on a same structural layer. Alternatively, for example, the film layers on a same layer may be layer structures formed through forming thin layers for forming specific patterns through a single film-forming process and then patterning the film layers with a same mask through a single patterning process. Depending on different specific patterns, a single patterning process may include multiple exposure, development or etching processes, and the specific patterns in the layer structures may be continuous or discontinuous. These specific patterns may also be arranged at different levels or have different thicknesses.

In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the product embodiments are substantially similar to the method embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The aforementioned are merely specific embodiments of the present disclosure, but a scope of the present disclosure is not limited thereto. Any modifications or replacements that would easily occurred to a person skilled in the art, without departing from the technical scope disclosed in the disclosure, should be encompassed in the scope of the present disclosure. Therefore, the scope of the present disclosure shall be subject to the scope defined by the appended claims.

1. A display substrate, comprising: a base substrate and a plurality of sub-pixels arranged on the base substrate, wherein at least one sub-pixel comprises a sub-pixel driving circuit and a light-emitting element, the light-emitting element comprises an anode pattern, and the anode pattern is coupled to the sub-pixel driving circuit; the display substrate further comprises:
a plurality of pixel definition patterns, an orthographic projection of at least one pixel definition pattern onto the base substrate at least partially overlapping with an orthographic projection of a boundary of a corresponding anode pattern onto the base substrate.

2. The display substrate according to claim 1, wherein the orthographic projection of the pixel definition pattern onto the base substrate fully covers the orthographic projection of the boundary of the corresponding anode pattern onto the base substrate.

3. The display substrate according to claim 1, wherein at least a portion of the orthographic projection of the pixel definition pattern onto the base substrate has an annular structure, and the annular structure is configured to define an opening region of a corresponding sub-pixel.

4. The display substrate according to claim 3, wherein at least a portion of the orthographic projection of the pixel definition pattern onto the base substrate has a circular-annular structure.

5. The display substrate according to claim 3, wherein the anode pattern comprises an anode main body and an anode connection member coupled to each other, and the anode connection member is coupled to a corresponding sub-pixel driving circuit;
the pixel definition pattern comprises a first sub-pattern and a second sub-pattern coupled to each other, an orthographic projection of the first sub-pattern onto the base substrate has an annular structure, the orthographic projection of the first sub-pattern onto the base substrate covers an orthographic projection of a boundary of a corresponding anode main body onto the base substrate, and an orthographic projection of the second sub-pattern onto the base substrate covers an orthographic projection of a corresponding anode connection member onto the base substrate.

6. The display substrate according to claim 1, wherein the pixel definition pattern comprises a black pixel definition pattern; an orthographic projection of the pixel definition pattern onto the base substrate at least partially overlaps with an orthographic projection of a corresponding sub-pixel driving circuit onto the base substrate.

7. The display substrate according to claim 1, wherein the display substrate further comprises a transparent data line, and at least a portion of an orthographic projection of the transparent data line onto the base substrate is located between orthographic projections of adjacent pixel definition patterns onto the base substrate.

8. The display substrate according to claim 1, wherein the display substrate further comprises a transparent reset signal line, and at least a portion of an orthographic projection of the transparent reset signal line onto the base substrate is located between orthographic projections of adjacent pixel definition patterns onto the base substrate.

9. The display substrate according to claim 1, wherein the display substrate comprises an initialization signal line, the initialization signal line comprises a transparent initialization portion, and at least a portion of an orthographic projection of the transparent initialization portion onto the base substrate is located between orthographic projections of adjacent pixel definition patterns onto the base substrate.

10. The display substrate according to claim 1, wherein the sub-pixel driving circuit comprises a data written-in transistor, the display substrate comprises a first scanning line, a gate electrode of the data written-in transistor is coupled to a corresponding first scanning line, the first scanning line comprises a first transparent scanning portion, an orthographic projection of the first transparent scanning portion onto the base substrate is located between orthographic projections of adjacent pixel definition patterns onto the base substrate.

11. The display substrate according to claim 1, wherein the sub-pixel driving circuit comprises a compensation transistor, the display substrate comprises a second scanning line, a gate electrode of the compensation transistor is coupled to a corresponding second scanning line, the second scanning line comprises a second transparent scanning portion, an orthographic projection of the second transparent scanning portion onto the base substrate is located between orthographic projections of adjacent pixel definition patterns onto the base substrate.

12. The display substrate according to claim 1, wherein the display substrate comprises a light-emission control signal line, the light-emission control signal line comprises a transparent light-emission control portion, at least a portion of an orthographic projection of the transparent light-emission control portion onto the base substrate is located between orthographic projections of adjacent pixel definition patterns onto the base substrate.

13. The display substrate according to claim 1, wherein the display substrate further comprises a power source line, the power source line comprises a transparent power source portion, and an orthographic projection of the transparent power source portion onto the base substrate is located between orthographic projections of adjacent pixel definition patterns onto the base substrate.

14. The display substrate according to claim 1, wherein the display substrate further comprises a cathode layer located on a side of the light-emitting element away from the base substrate, the cathode layer comprises a plurality of cathode openings, and at least a portion of an orthographic projection of at least one cathode opening onto the base substrate is located between orthographic projections of adjacent pixel definition patterns onto the base substrate.

15. The display substrate according to claim 14, wherein the orthographic projection of the cathode opening onto the base substrate is between the orthographic projections of the adjacent pixel definition patterns onto the base substrate.

16. The display substrate according to claim 3, wherein the display substrate further comprises an encapsulation layer and a plurality of black matrix patterns, the encapsulation layer is located between the plurality of black matrix patterns and the base substrate, an orthographic projection of at least one black matrix pattern onto the base substrate at least partially overlaps with an orthographic projection of a corresponding pixel definition pattern onto the base substrate.

17. The display substrate according to claim 16, wherein the orthographic projection of the black matrix pattern onto the base substrate has an anular structure, and an orthographic projection of an inner boundary of the black matrix pattern onto the base substrate surrounds an orthographic projection of an inner boundary of the corresponding pixel definition pattern onto the base substrate.

18. The display substrate according to claim 17, wherein an orthographic projection of an outer boundary of the pixel definition pattern onto the base substrate surrounds an orthographic projection of the corresponding black matrix pattern onto the base substrate.

19. The display substrate according to claim 1, wherein the display substrate comprises a first display region and a second display region, the second display region is located on at least one side of the first display region, and a light transmittance of the first display region is greater than a light transmittance of the second display region, and the plurality of pixel definition patterns is located in the first display region.

20. A display device comprising the display substrate according to claim 1, and a sensor located on a non-display side of the display substrate, wherein an orthographic projection of the sensor onto the display substrate overlaps with the first display region of the display substrate.
